(19) United States
(12) Patent Application Publication
(10) Pub. No.: US 2006/0284179 A1
(43) Pub. Date: Dec. 21, 2006

(54) Silicon thin film transistor and method of manufacturing the same

(76) Inventors: Ji-sim Jung, Incheon-si (KR); Do-Young Kim, Suwon-si (KR); Jong-man Kim, Suwon-si (KR); Jang-yeon Kwon, Seongnam-si (KR); Takashi Noguchi, Yongin-si (KR)

Correspondence Address: CANTOR COLBURN, LLP, 55 GRIFFIN ROAD SOUTH, BLOOMFIELD, CT, 06002, US

(21) Appl. No.: 11/455,559

(22) Filed: Jun. 19, 2006

(30) Foreign Application Priority Data
Jun. 18, 2005 (KR) 10-2005-0052725

(51) Int. Cl. H01L 29/04

(52) U.S. Cl. 257/59

(57) ABSTRACT

A silicon thin film transistor (“TFT”) and method of manufacturing the same are provided where the silicon TFT includes buffer layers deposited on both surfaces of a substrate, respectively, and a silicon channel is deposited on one of the buffer layers. A gate insulator is deposited on the silicon channel, and a gate is deposited on the gate insulator. Because of the buffer layers deposited on both surfaces of the substrate, the bending of the substrate is prevented and the silicon TFT has good operating performance.

This application claims priority to Korean Patent Application No. 10-2005-0052725, filed on Jun. 18, 2005 and all the benefits accruing therefrom under 35 U.S.C. §119, and the contents of which in its entirety are herein incorporated by reference.

### BACKGROUND OF THE INVENTION

1. Field of the Invention

The present invention relates to a thin film transistor (“TFT”) and a method of manufacturing the same, and more particularly, to a silicon TFT and a method of manufacturing the same in which a silicon layer is formed on a substrate vulnerable to heat, such as a plastic substrate.

2. Description of the Related Art

Since poly crystalline silicon (“p-Si”) has higher mobility than amorphous silicon (“a-Si”), p-Si is applied not only to flat panel displays (“FPDs”) but also to various electronic devices, such as solar batteries.

In general, a material resistant to heat, for example, glass, is used to obtain high-quality p-Si. Formation of p-Si on the material resistant to heat, such as glass, is performed using a high-temperature a-Si deposition process, such as a plasma-enhanced chemical vapor deposition (“PECVD”) process. However, it is known that the above-described conventional method leads to formation of p-Si with a crystal grain size of only about 3000 to 4000 Å and it is difficult to further increase the crystal grain size.

In recent years, there have been studies on a method of forming a p-Si electronic device on a plastic substrate. In order to prevent thermal deformation of the plastic substrate, a low-temperature process, such as a sputtering process, should be necessarily adopted. The low-temperature process is required to protect the plastic substrate from a thermal shock and inhibit generation of defects during the manufacture of a device. Although the plastic substrate is vulnerable to heat, the plastic substrate is light-weight, flexible, and inexpensive and is therefore being considered as a substrate for FPDs.

A method for preventing a plastic substrate from being damaged during formation of a Si channel on the plastic substrate has been proposed by Carry et al. in U.S. Pat. No. 5,817,550.

FIG. 1 is a cross sectional view of a stacked structure of a conventional TFT.

Referring to FIG. 1, a SiO₂ buffer layer is prepared on a substrate vulnerable to heat, such as a plastic substrate, and a Si channel is deposited on the SiO₂ buffer layer. A SiO₂ gate insulator is deposited on the Si channel, and a gate is deposited on the SiO₂ gate insulator. A p-Si source and a p-Si drain are doped on both sides of the Si channel, respectively. A SiO₂ interlayer dielectric (“ILD”) covers the gate. A source electrode is connected to the p-Si source, and a drain electrode is connected to the p-Si drain.

However, as shown in FIG. 2, the plastic substrate is bent due to a stress difference between the plastic substrate and the buffer layer deposited on the plastic substrate during the manufacture of the TFT having the above-described structure. The bending of the plastic substrate adversely affects the performance of the TFT that is manufactured in a subsequent process.

### BRIEF SUMMARY OF THE INVENTION

The present invention provides a silicon thin film transistor (“TFT”) and a method of manufacturing the same that effectively prevent the bending of a substrate, thus improving the performance of the TFT.

According to exemplary embodiments of the present invention, there is provided a silicon TFT including a plastic substrate having a first surface and a second surface on an opposite side from the first surface, a first buffer layer and a second buffer layer deposited on the first and second surfaces of the plastic substrate, respectively, a silicon (“Si”) channel deposited on the first buffer layer, a gate insulator deposited on the Si channel, and a gate deposited on the gate insulator.

The substrate may be a flexible plastic substrate.

According to another exemplary embodiment of the present invention, a thin film transistor includes a substrate formed from a flexible material and having a first surface and an opposite second surface, a first buffer layer deposited on the first surface, and a second buffer layer deposited on the second surface, the plastic substrate disposed between the first buffer layer and the second buffer layer, wherein the first buffer layer and the second buffer layer are formed of a material preventing the substrate from bending.

According to another exemplary embodiment of the present invention, there is provided a method of manufacturing a TFT including a substrate having a first surface and a second surface on an opposite side from the first surface, a silicon thin layer deposited on the substrate, a gate corresponding to the silicon thin layer, and a gate insulator interposed between the silicon thin layer and the gate. The method includes forming first and second buffer layers on the first and second surfaces of the substrate, respectively, before forming the silicon thin layer, and forming the silicon thin layer on the first buffer layer formed on the first surface of the substrate.

The formation of the silicon thin layer may include forming an amorphous silicon (“a-Si”) layer on the first buffer layer, and crystallizing the a-Si layer through a thermal process.

The first and second buffer layers may be formed of a same material, for example, one material selected from a group consisting of SiO₂, SiNx, and SiON.

### BRIEF DESCRIPTION OF THE DRAWINGS

The above and other features and advantages of the present invention will become more apparent by describing exemplary embodiments thereof with reference to the attached drawings in which:

FIG. 1 is a cross sectional view of a conventional thin film transistor (“TFT”);

FIG. 2 is an image showing the bending of a plastic substrate including a buffer layer formed on one lateral surface during manufacture of a TFT as shown in FIG. 1;

FIG. 3 is a cross sectional view of an exemplary TFT according to an exemplary embodiment of the present invention;

FIGS. 4A through 4K are cross sectional views illustrating an exemplary method of manufacturing an exemplary TFT according to an exemplary embodiment of the present invention;

FIG. 5A is a scanning electron microscope (“SEM”) image showing the surface of a p-Si layer formed by a conventional method;

FIG. 5B is a graph showing the characteristics of a TFT formed by the conventional method;

FIGS. 6A and 6B are SEM images showing the p-Si layer formed by the conventional method and an exemplary p-Si layer formed according to exemplary embodiments of the present invention, respectively;

FIGS. 7A and 7B are SEM images showing the quality of exemplary p-Si layers with respect to the roughness of exemplary buffer layers; and

FIG. 8 is a graph of the maximum laser energy density with Si film endurance with respect to the thickness of exemplary buffer layers of exemplary TFTs according to exemplary embodiments of the present invention.

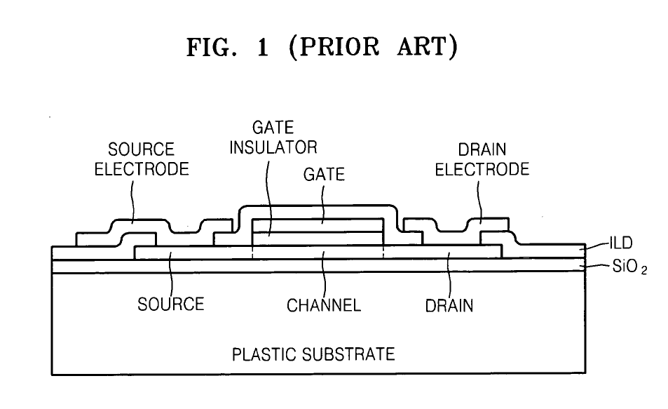

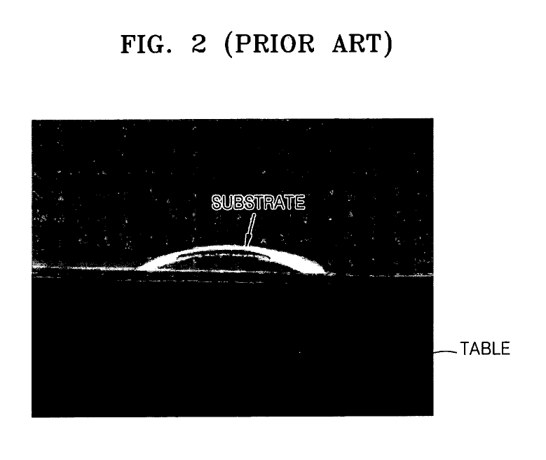

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper”and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

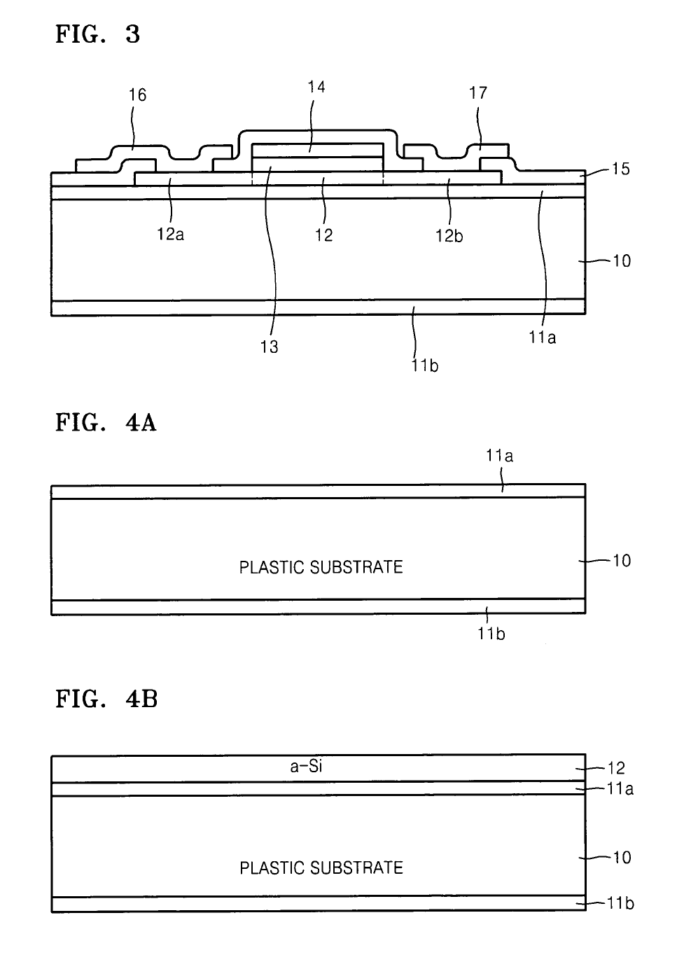

FIG. 3 is a cross sectional view of an exemplary TFT according to an exemplary embodiment of the present invention.

Referring to FIG. 3, a substrate 10, such as a flexible plastic substrate, includes a first surface and an opposite second surface. A first buffer layer 11a is deposited on the first surface of the plastic substrate 10 that is opposite to the second surface, and a second buffer layer 11b is deposited on the second surface of the plastic substrate 10. The first and second buffer layers 11a and 11b may be formed of silicon dioxide SiO₂, silicon nitride SiN, or silicon oxynitride SiON. Also, the first and second buffer layers 11a and 11b may be formed of the same material to a thickness of 4000 Å or more and to a roughness of 40 Å (root mean square or “rms”) or less, and may have the same thickness. The first and second buffer layers 11a and 11b formed on opposing first and second surfaces of the flexible plastic substrate 10 can prevent the bending of the plastic substrate 10. Since the plastic substrate 10 does not bend due to the buffer layers 11a and 11b, a high-quality silicon thin layer can be obtained in a subsequent process.

A silicon thin layer 12 is prepared as a current channel on the first buffer layer 11a. A gate insulator 13, which may be obtained using a deposition process, is disposed on the silicon thin layer 12, and a gate 14 is disposed on the gate insulator 13. A source 12a and a drain 12b are doped on both sides of the silicon thin layer 12, respectively, in regions not overlapped by the gate 14 and the gate insulator 13. An interlayer dielectric (“ILD”) 15 covers the gate 14, and may further cover exposed portions of the source 12a, drain 12b, and the first buffer layer 11a. The ILD 15 includes through holes corresponding to a source electrode 16 and a drain electrode 17, respectively. The source electrode 16 is connected to the source 12a, and the drain electrode 17 is connected to the drain 12b.

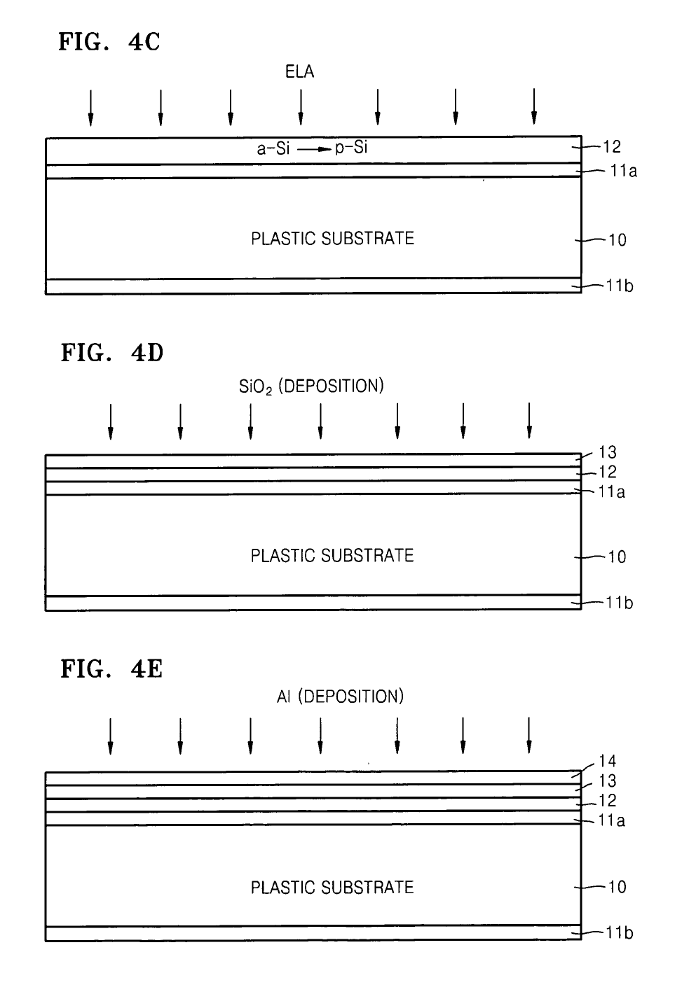

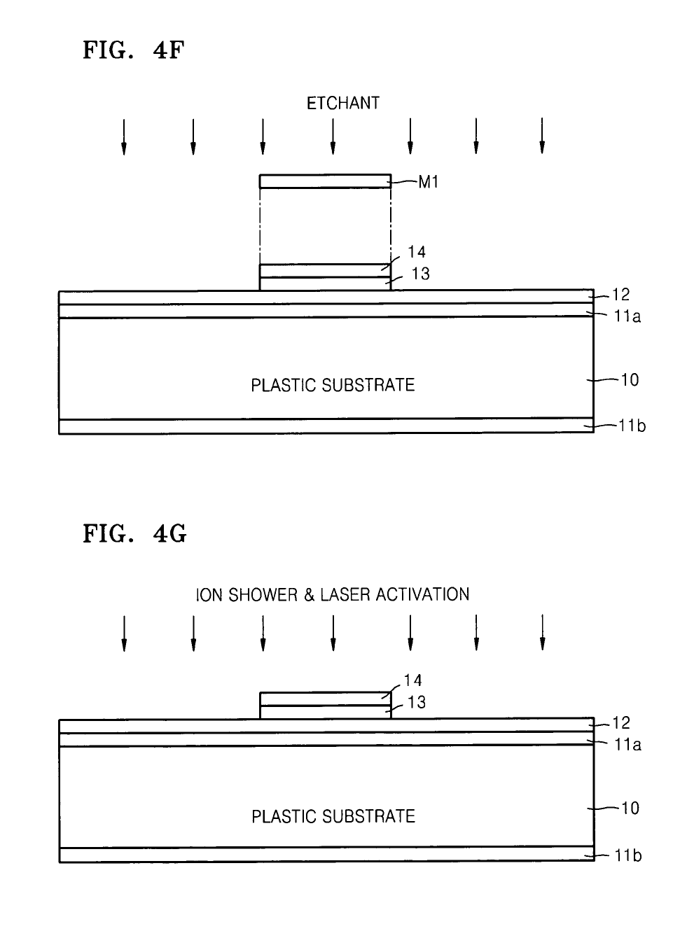

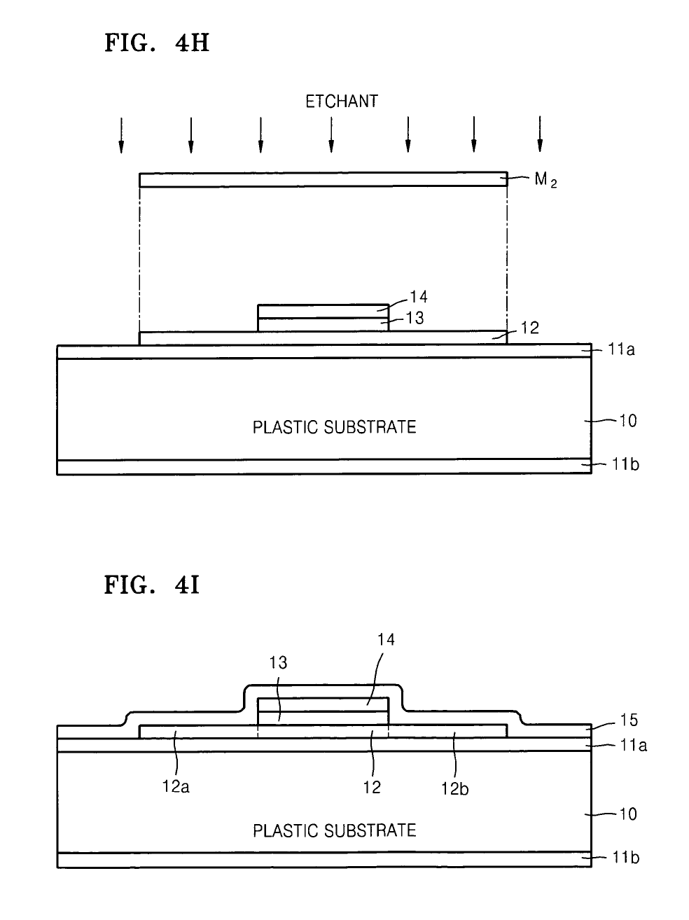

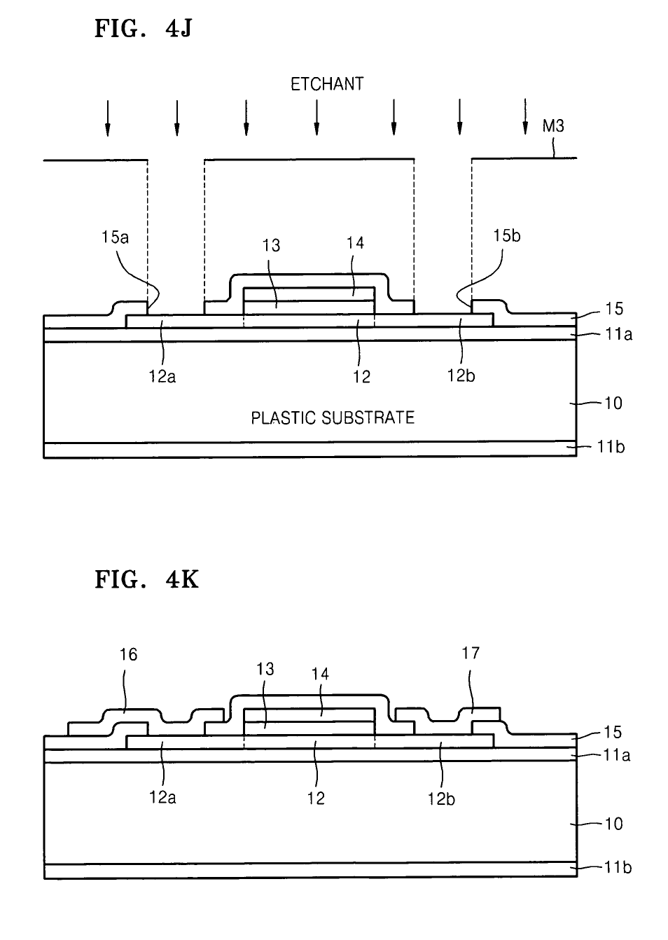

Hereinafter, an exemplary method of manufacturing an exemplary TFT according to an exemplary embodiment of the present invention will be described with reference to FIGS. 4A through 4K.

Referring to FIG. 4A, a plastic substrate 10, used for forming a polycrystalline silicon (“p-Si”) thin layer, is prepared. A first buffer layer 11a and a second buffer layer 11b are formed to ensure electrical insulation on a first surface and a second surface of the plastic substrate 10, respectively. The first and second buffer layers 11a and 11b are formed of an oxidized material, such as SiO₂, SiN, or SiON.

Referring to FIG. 4B, a thin layer 12 of amorphous silicon (“a-Si”) is formed on the first buffer layer 11a formed on the first surface of the plastic substrate 10. The thin layer 12 of a-Si may be formed using a physical vapor deposition (“PVD”) process, such as a sputtering process. In this case, the sputtering process, which is a low-temperature deposition technique, employs a sputtering gas, such as noble gas (e.g., Ar gas). The thin layer 12 of a-Si may be controlled to a thickness of 50 nm. Also, the sputtering process is performed at a sputtering power of 200 W and under a gas pressure of 5 mTorr.

Referring to FIG. 4C, the thin layer 12 of a-Si is annealed using an excimer laser annealing (“ELA”) process, thereby forming a desired thin layer 12 of p-Si, as may hereinafter be referred to as the p-Si layer 12, or the silicon thin layer 12.

Referring to FIG. 4D, a gate insulator 13 is formed using SiO₂ on the p-Si layer 12. The SiO₂ layer for the gate insulator 13 is deposited using an inductively coupled plasma chemical vapor deposition (“ICP-CVD”) process, a plasma-enhanced CVD (“PECVD”), or a sputtering process until the gate insulator 13 reaches a desired thickness of 100 to 200 nm.

Referring to FIG. 4E, a metal layer, such as, but not limited to, an aluminium Al layer, is deposited on the gate insulator 13, thereby forming a gate 14. At this stage of the manufacturing method, since the gate insulator 13 and the gate 14 do not have shapes appropriate for given functions, the gate insulator 13 and the gate 14 are properly patterned in a subsequent process.

Referring to FIG. 4F, the gate 14 and the gate insulator 13 are dry etched using a first mask M1. The first mask M1 has a pattern shape corresponding to a desired shape of the gate. Thus, the gate 14 and the gate insulator 13 are patterned in the same shape as the first mask M1. In this process, a portion of the silicon thin layer 12 is exposed by the removal of portions of the metal layer and the SiO₂ layer not needed for the gate 14 and the gate insulator 13.

Referring to FIG. 4G, the exposed portion of the silicon thin layer 12 is showered with ions and activated using, for example, a 308-nm xenon chloride XeCl excimer laser apparatus.

Referring to FIG. 4H, the exposed portion of the silicon thin layer 12 is dry etched using a second mask M2, larger than the first mask M1, thereby forming a source 12a and a drain 12b disposed with respect to opposing sides of the gate 14. The other portion of the silicon thin layer 12, which is covered with the gate 14 and disposed between the source 12a and the drain 12b, remains undoped with p-Si and will function as a channel for the TFT.

Referring to FIG. 41, an ILD 15 is formed using SiO2 on the entire surface of the resultant structure shown in FIG. 4H using an ICP-CVD process, a PECVD process, or a sputtering process. The ILD 15 is formed to a thickness greater than about 3000 nm.

Referring to FIG. 4J, a source contact hole 15a and a drain contact hole 15b are formed in the SiO₂ ILD 15 using a third mask M3. The source contact hole 15a exposes a portion of the source 12a and the drain contact hole 15b exposes a portion of the drain 12b.

Referring to FIG. 4K, a source electrode 16 and a drain electrode 17 are formed on portions of the ILD 15 and extend through the source and drain contact holes 15a and 15b so as to contact the source 12a and drain 12b, respectively. As a result, an exemplary TFT according to an exemplary embodiment of the present invention is completed.

As described above, the present invention solves problems caused by a low-temperature thermal process when a TFT is formed on a substrate vulnerable to heat, for example, a plastic substrate. In a conventional method, the thermal conductivity of a substrate deteriorates, a silicon film partially agglomerates (gathers into jumbled masses or clusters) due to thermal accumulation during an ELA process, and a silicon thin layer has high surface roughness and partially delaminates. These problems are closely associated with one another, and the bending of the substrate greatly affects the partial delamination and agglomeration of the silicon thin layer.

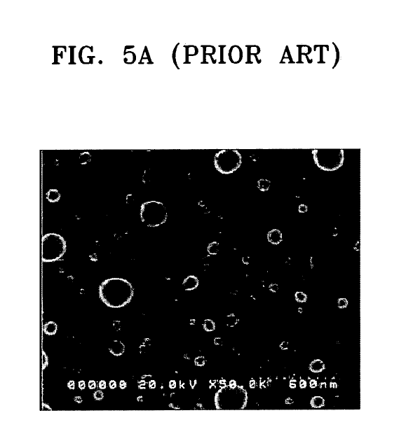

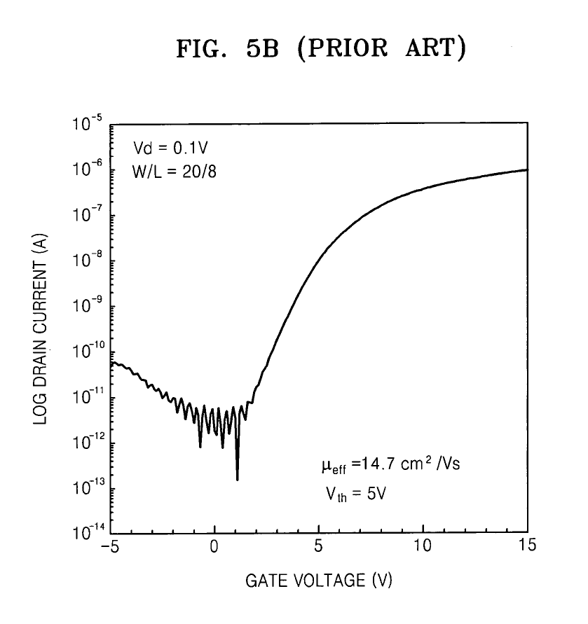

FIG. 5A is a scanning electron microscope (“SEM”) image showing the surface of a conventional p-Si thin layer that partially agglomerates. Here, the conventional p-Si thin layer is obtained by irradiating excimer laser beams five times at an energy density of 400 mJ/cm². Referring to FIG. 5A, it can be seen that a plurality of agglomerations (as shown by the bright regions in the image) are generated in the p-Si thin layer.

FIG. 5B is a graph showing the characteristics of a TFT formed by the conventional method as described with reference to FIG. 5A. Referring to FIG. 5B, the conventional p-Si thin layer has a mobility of only 14.7 cm²/Vs that is much lower than an average mobility of about 100 cm²/Vs.

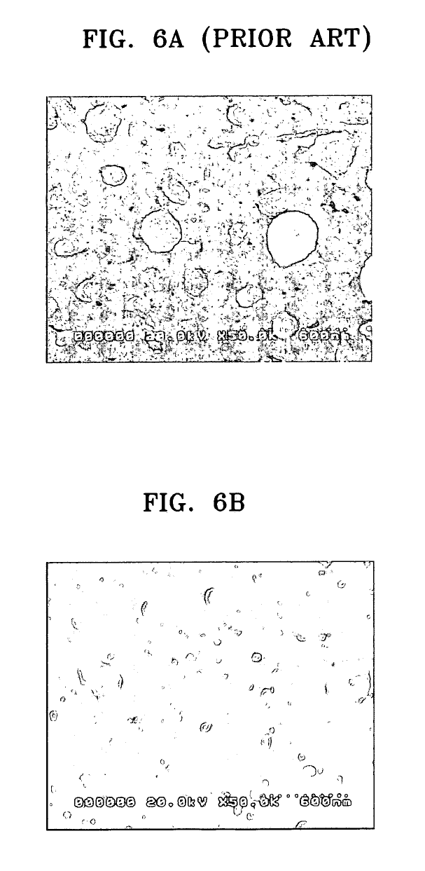

FIGS. 6A and 6B are SEM images showing the surface of the p-Si layer formed by the conventional method and the surface of an exemplary p-Si layer formed according to an exemplary embodiment of the present invention, respectively. In FIG. 6A, since a buffer layer is formed on only one surface of a plastic substrate, the plastic substrate is bent. Thus, the conventional p-Si layer is obtained by annealing an a-Si layer formed on the bent substrate using an ELA process. In FIG. 6B, SiO₂ buffer layers are formed on both sides of a plastic substrate according to the present invention. Thus, the plastic substrate is not bent. Thereafter, an a-Si layer is deposited on the plastic substrate and annealed using an ELA process. By comparing FIG. 6A with FIG. 6B, it can be observed that the exemplary p-Si layer of an exemplary embodiment of the present invention has lower roughness and fewer agglomerations than the conventional p-Si layer.

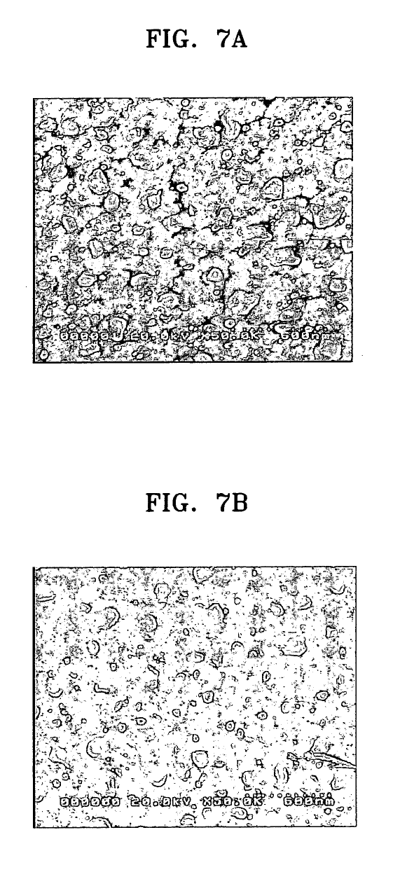

FIGS. 7A and 7B are SEM images showing the quality of exemplary p-Si layers with respect to the roughness of exemplary buffer layers. Specifically, FIG. 7A shows the surface of a p-Si layer formed on a buffer layer with a roughness of about 100 Å, and FIG. 7B shows the surface of a p-Si layer formed on a buffer layer with a roughness of about 30 Å. As can be seen from FIGS. 7A and 7B, the lower the roughness of the buffer layer is, the better the quality of the p-Si layer becomes.

In an example of the exemplary embodiment of the present invention, when buffer layers were formed on both sides of a substrate and a TFT was formed on one of the buffer layers, the TFT could exhibit the following characteristics as shown in Table 1.

TABLE 1

| TFT Parameters | Value (at Vds = 0.1 V) |
|---|---|
| Ion/Ioff current ratio | >4 * 10⁶ |
| Ion_max [A] | 2.4 * 10⁻⁶ |
| Vth [V] | 2 |
| Subthreshold Swing [V/dec.] | 0.1 |
| Mobility (μ_{eff.}[cm²/Vs]) | 258 |

As can be seen from Table 1, a sample of a p-Si layer according to an exemplary embodiment of the present invention had a very high mobility and a very high on/off current ratio. Here, the sample of the p-Si layer had a width of 20□ and a length of 20□ in channel size.

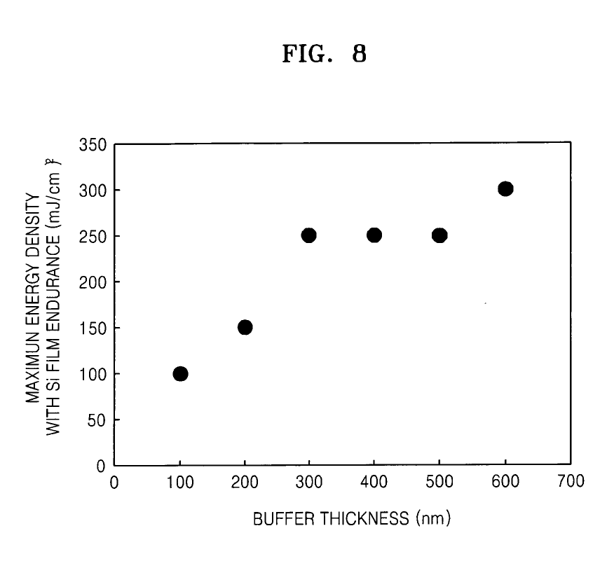

FIG. 8 is a graph of maximum energy density with respect to the thickness of exemplary buffer layers of exemplary TFTs according to exemplary embodiments of the present invention. Here, the maximum energy density refers to the maximum value at which a thin layer can be poly-crystallized without delamination after an ELA process.

Referring to FIG. 8, as the thickness of the buffer layer increases, the applicable maximum energy density also increases. In particular, when the buffer layer has a thickness of about 300 to 500 nm, maximum energy density is maintained at a constant value of about 250 mJ/cm².

Meanwhile, according to another experiment, when an a-Si thin layer formed on a conventional plastic substrate was poly-crystallized at a higher ELA energy than 400 mJ/cm², agglomeration was generated in the resultant p-Si layer. On the other hand, an exemplary p-Si layer according to an exemplary embodiment of the present invention had no agglomeration even at an ELA energy of about 600 mJ/cm². Therefore, exemplary embodiments of the present invention enable the crystallization of an a-Si layer at an energy higher than in the case of the conventional method.

According to exemplary embodiments of the present invention as described above, a substrate can be thermally stabilized, and thus the bending of the substrate can be prevented. As a result, a p-Si layer has fewer agglomerations and lower roughness. Also, since a crystallization process can be carried out even at a high energy density, the p-Si layer can improve in quality.

Further, because buffer layers are formed on both sides of the substrate, the substrate is not bent and can be protected during subsequent chemical processes. In addition, the buffer layers inhibit the permeation of moisture into the substrate, thus preventing moisture-induced defects.

The exemplary silicon TFT and exemplary method of manufacturing the same according to exemplary embodiments of the present invention can be applied to the manufacture of, by example only, flat panel displays (“FPDs”), such as active-matrix liquid crystal displays (“AMLCDs”) and active-matrix organic light emitting displays (“AMOLEDs”), which make use of a substrate vulnerable to heat, for example, a plastic substrate.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A silicon thin film transistor comprising:
a plastic substrate having a first surface and a second surface on an opposite side from the first surface;
a first buffer layer and a second buffer layer deposited on the first and second surfaces of the plastic substrate, respectively;
a silicon channel deposited on the first buffer layer;
a gate insulator deposited on the silicon channel; and
a gate deposited on the gate insulator.

2. The silicon thin film transistor of claim 1, wherein the silicon channel is formed of poly crystalline silicon.

3. The silicon thin film transistor of claim 1, wherein each of the first and second buffer layers has a thickness of 4000 Å or more.

4. The silicon thin film transistor of claim 3, wherein each of the first and second buffer layers has a roughness of 40 Å or less.

5. The silicon thin film transistor of claim 1, wherein each of the first and second buffer layers has a roughness of 40 Å or less.

6. The silicon thin film transistor of claim 1, wherein the first and second buffer layers are formed using a same material and are formed with a same thickness.

7. The silicon thin film transistor of claim 6, wherein the first and second buffer layers are formed of one material selected from a group consisting of SiO₂, SiN, and SiON.

8. The silicon thin film transistor of claim 1, wherein the plastic substrate is disposed between the first buffer layer and the second buffer layer.

9. The silicon thin film transistor of claim 1, wherein the plastic substrate does not bend after deposition of the first buffer layer and the second buffer layer thereon.

10. The silicon thin film transistor of claim 9, wherein the plastic substrate is flexible prior to deposition of the first buffer layer and the second buffer layer thereon.

11. A thin film transistor comprising:
a substrate formed from a flexible material and having a first surface and an opposite second surface;
a first buffer layer deposited on the first surface; and,
a second buffer layer deposited on the second surface, the plastic substrate disposed between the first buffer layer and the second buffer layer;
wherein the first buffer layer and the second buffer layer are formed of a material preventing the substrate from bending.

12. The thin film transistor of claim 11, further comprising a silicon layer formed on the first buffer layer.

13. The thin film transistor of claim 11, wherein the material of the first buffer layer and the second buffer layer prevents the substrate from deforming due to thermal processes.

14. The thin film transistor of claim 11, wherein the substrate is plastic and the first and second buffer layers are formed on one material selected from a group consisting of SiO₂, SiN, and SiON.

15. A method of manufacturing a silicon thin film transistor including a substrate having a first surface and a second surface on an opposite side from the first surface, a silicon thin layer deposited on the substrate, a gate corresponding to the silicon thin layer, and a gate insulator interposed between the silicon thin layer and the gate, the method comprising:
forming first and second buffer layers on the first and second surfaces of the substrate, respectively, before forming the silicon thin layer; and
forming the silicon thin layer on the first buffer layer formed on the first surface of the substrate.

16. The method of claim 15, wherein forming the first and second buffer layers includes forming each of the first and second buffer layers to a thickness of 4000 Å or more.

17. The method of claim 16, wherein forming the first and second buffer layers includes forming each of the first and second buffer layers to a roughness of 40 Å or less.

18. The method of claim 15, wherein forming the first and second buffer layers includes forming each of the first and second buffer layers to a roughness of 40 Å or less.

19. The method of claim 15, wherein forming the silicon thin layer comprises:
forming an amorphous silicon layer on the first buffer layer; and
poly-crystallizing the amorphous silicon layer through a thermal process.

20. The method of claim 19, wherein forming the first and second buffer layers includes forming the first and second buffer layers using a same material.

21. The method of claim 20, wherein the first and second buffer layers are formed of one material selected from a group consisting of SiO₂, SiN, and SiON.

22. The method of claim 15, wherein forming the first and second buffer layers includes forming buffer layers using a same material.

23. The method of claim 22, wherein the first and second buffer layers are formed of one material selected from a group consisting of SiO₂, SiN, and SiON.

24. The method of claim 15, wherein the first and second buffer layers are formed of one material selected from a group consisting of SiO₂, SiN, and SiON.

25. The method of claim 15, wherein the substrate is flexible prior to forming the first and second buffer layers thereon, and wherein forming the first and second buffer layers on the first and second surfaces of the substrate prevents the substrate from bending.
